(19) United States
(12) Patent Application Publication
(10) Pub. No.: US 2025/0164560 A1
(43) Pub. Date: May 22, 2025

(54) POWER GENERATION SYSTEM AND CONTROL METHOD

(71) Applicant: MITSUBISHI HEAVY INDUSTRIES, LTD, Tokyo (JP)

(72) Inventors: Akira YASUGI, Tokyo (JP); Masao TERAZAKI, Tokyo (JP)

(21) Appl. No.: 18/861,959

(22) PCT Filed: Mar. 24, 2023
(86) PCT No.: PCT/JP2023/011931

§ 371 Date: Oct. 31, 2024

(30) Foreign Application Priority Data
May 9, 2022 (JP) 2022-076850

(51) Int. Cl. G01R 31/36; F01D 15/10; F02C 7/268; G01R 31/387

(52) U.S. Cl. CPC G01R 31/3647; F01D 15/10; F02C 7/268; G01R 31/387

(57) ABSTRACT

A power generation system comprises a rotating electric machine, a plurality of storage batteries, a discharge control unit for controlling the discharging of the plurality of storage batteries, and an abnormality detection unit for detecting abnormalities in the storage batteries. When the power used to start the rotating electric machine is supplied from the plurality of storage batteries by the discharging from the multiple storage batteries and the abnormality detection unit has detected an abnormality in a storage battery, the discharge control unit increases the power discharged by other storage batteries having no abnormalities detected so as to cover the discharge portion from the storage battery having the abnormality detected, after the discharge portion from the storage battery having the abnormality detected has been supplied from a grid.

### TECHNICAL FIELD

The present disclosure relates to a power generation system and a control method. Priority is claimed to Japanese Patent Application No. 2022-076850, filed May 9, 2022, the content of which is incorporated herein by reference.

### BACKGROUND ART

PTL 1 discloses a rotary machine (gas turbine power generation device) that uses a DC motor which uses a storage battery as a power generation source and as an activation device.

### CITATION LIST

### Patent Literature

[PTL 1] Japanese Unexamined Patent Application Publication No. 2009-150362

### SUMMARY OF INVENTION

### Technical Problem

In the rotary machine according to PTL 1, there is a problem that, for example, when a storage battery becomes abnormal, the rotary machine cannot be activated.

The present disclosure has been made to solve the above problems, and an object of the present disclosure is to provide a power generation system and a control method capable of appropriately coping with an abnormality of a storage battery for supplying power to an activation device of a rotary machine.

### Solution to Problem

In order to solve the above problems, a power generation system according to the present disclosure includes a rotary machine, a plurality of storage batteries, a discharge control unit that controls discharging of the plurality of storage batteries, and an abnormality detection unit that detects an abnormality of the storage battery, in which in a case where power used for activation of the rotary machine is supplied from the plurality of storage batteries by the discharging from the plurality of storage batteries, when the abnormality detection unit detects the abnormality of the storage batteries, the discharge control unit supplies, from a grid, a discharge amount from the storage battery in which the abnormality has been detected, and then increases discharge power of the other storage batteries in which the abnormality has not been detected, to cover the discharge amount from the storage battery in which the abnormality has been detected.

A control method according to the present disclosure is a control method of a power generation system including a rotary machine, a plurality of storage batteries, a discharge control unit that controls discharging of the plurality of storage batteries, and an abnormality detection unit that detects an abnormality of the storage battery, the control method including:
causing, in a case where power used for activation of the rotary machine is supplied from the plurality of storage batteries by the discharging from the plurality of storage batteries, when the abnormality detection unit detects the abnormality of the storage batteries, the discharge control unit supplies, from a grid, a discharge amount from the storage battery in which the abnormality has been detected, and then increases discharge power of the other storage batteries in which the abnormality has not been detected, to cover the discharge amount from the storage battery in which the abnormality has been detected.

### Advantageous Effects of Invention

According to the power generation system and the control method of the present disclosure, it is possible to appropriately cope with an abnormality of the storage battery for supplying power to the activation device of the gas turbine.

### BRIEF DESCRIPTION OF DRAWINGS

FIG. 1 is a configuration diagram showing a configuration example of a power generation system according to an embodiment of the present disclosure.

FIG. 2 is a schematic diagram showing an operation example of the power generation system according to the embodiment of the present disclosure.

FIG. 3 is a schematic diagram showing an example of an activation process of a gas turbine according to the embodiment of the present disclosure.

FIG. 4 is a schematic diagram for describing an operation example of the power generation system according to the embodiment of the present disclosure.

FIG. 5 is a flowchart showing an operation example of the power generation system according to the embodiment of the present disclosure.

FIG. 6 is a flowchart showing an operation example of the power generation system according to the embodiment of the present disclosure.

FIG. 7 is a schematic diagram for describing an operation example of the power generation system according to the embodiment of the present disclosure.

FIG. 8 is a schematic diagram for describing an operation example of the power generation system according to the embodiment of the present disclosure.

FIG. 9 is a schematic diagram for describing an operation example of the power generation system according to the embodiment of the present disclosure.

FIG. 10 is a flowchart showing an operation example of the power generation system according to the embodiment of the present disclosure.

FIG. 11 is a flowchart showing an operation example of the power generation system according to the embodiment of the present disclosure.

FIG. 12 is a schematic diagram for describing an operation example of the power generation system according to the embodiment of the present disclosure.

FIG. 13 is a schematic diagram for describing an operation example of the power generation system according to the embodiment of the present disclosure.

FIG. 14 is a schematic diagram for describing an operation example of the power generation system according to the embodiment of the present disclosure.

FIG. 15 is a schematic diagram for describing an operation example of the power generation system according to the embodiment of the present disclosure.

FIG. 16 is a schematic diagram for describing an operation example of the power generation system according to the embodiment of the present disclosure.

FIG. 17 is a schematic diagram for describing an operation example of the power generation system according to the embodiment of the present disclosure.

FIG. 18 is a schematic block diagram showing a configuration of a computer according to at least one embodiment.

### DESCRIPTION OF EMBODIMENTS

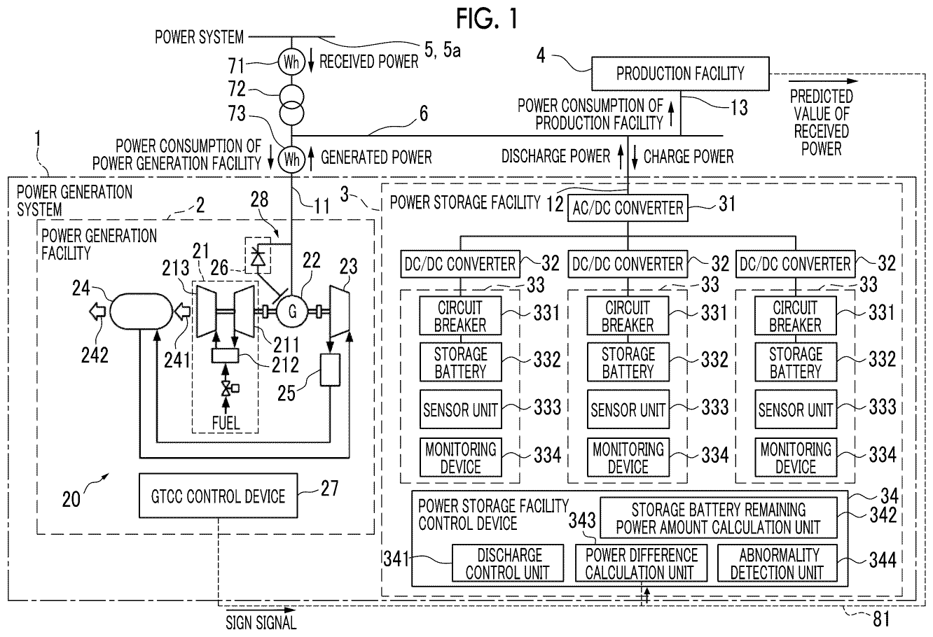

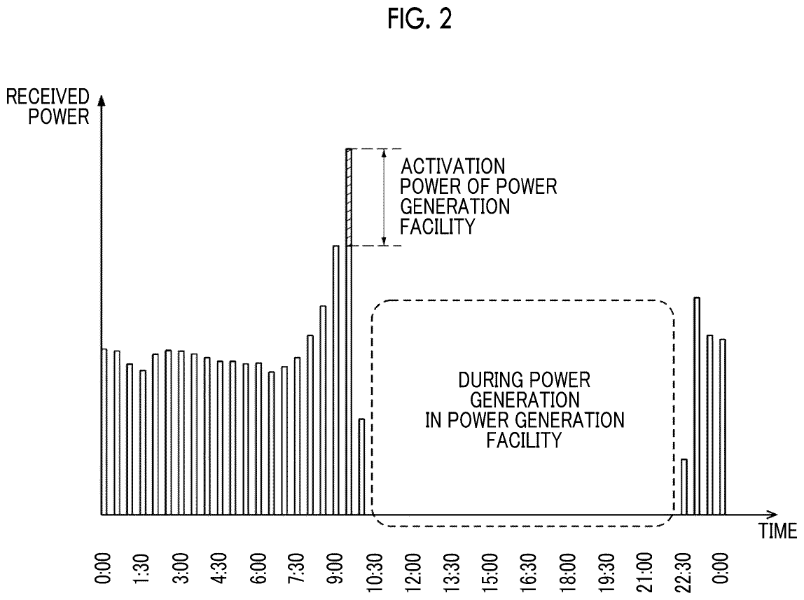

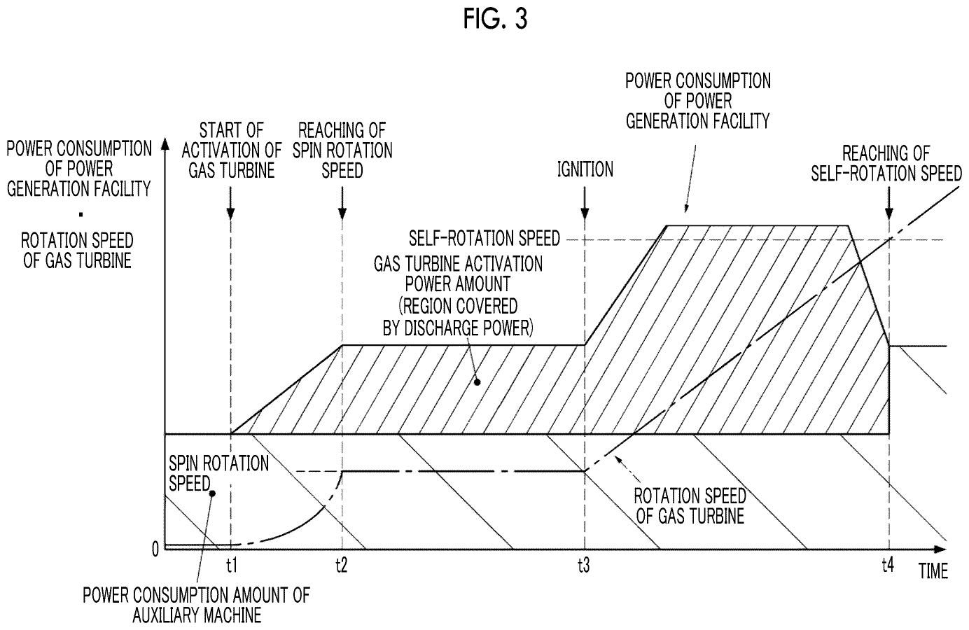

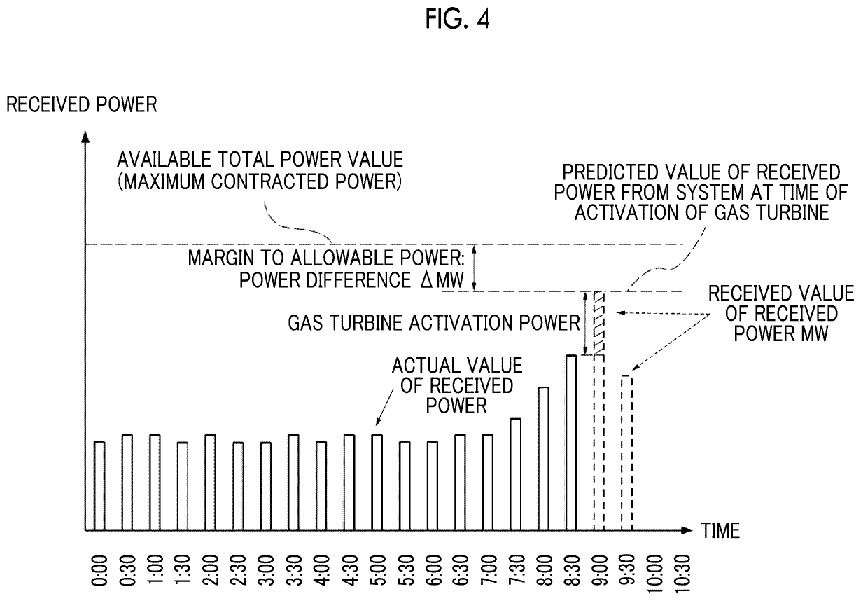

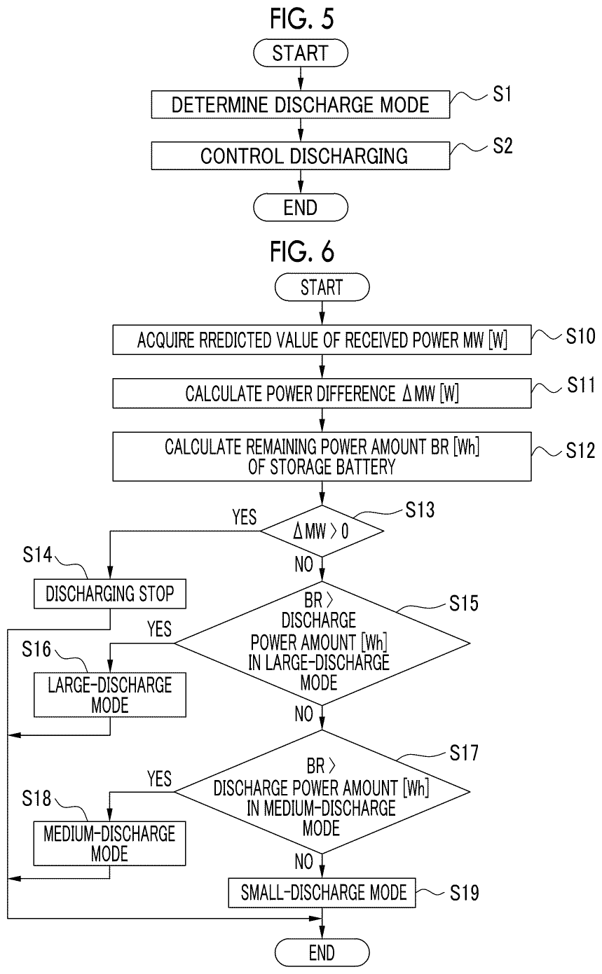

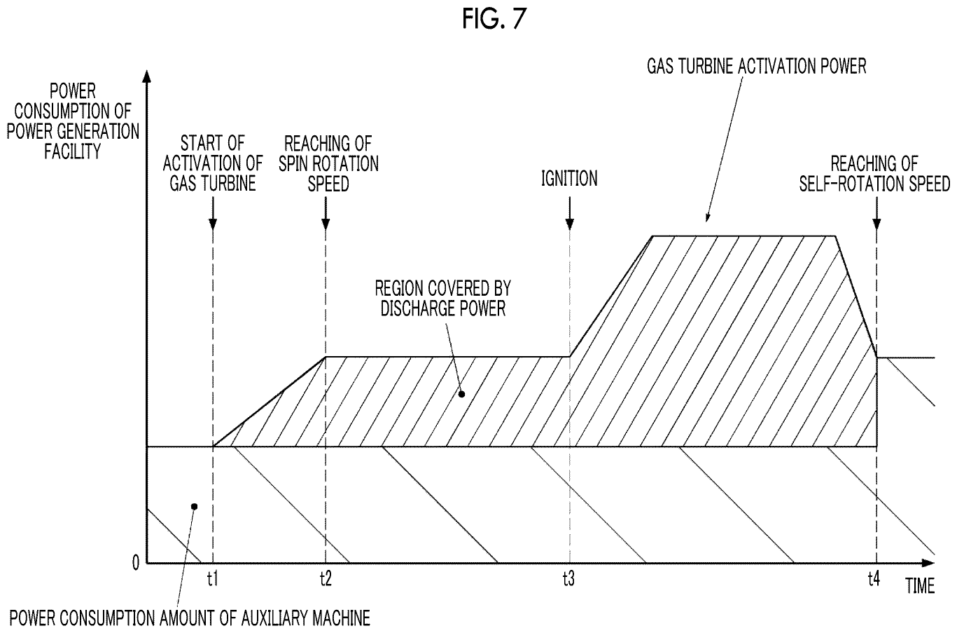

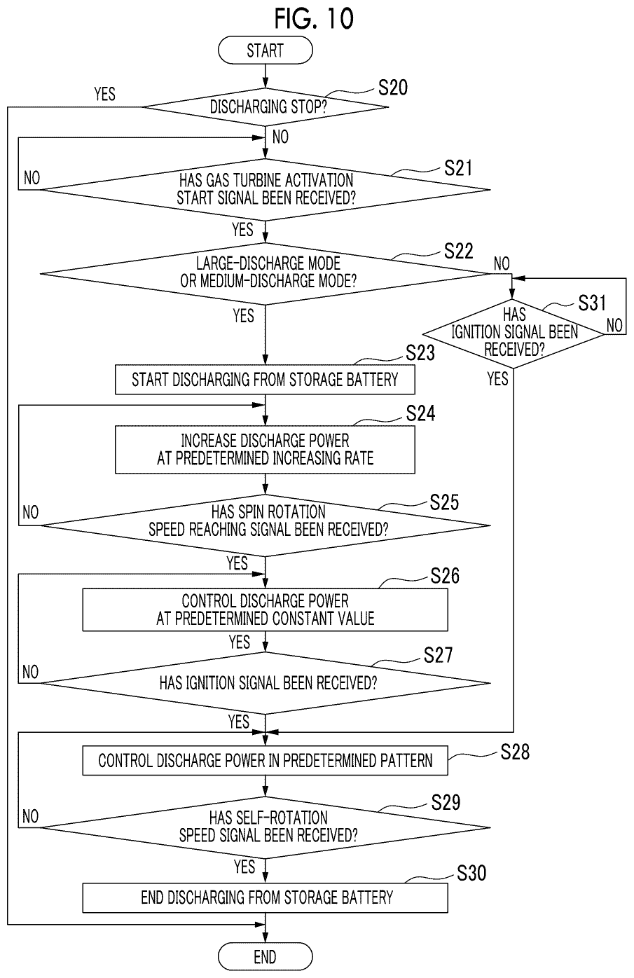

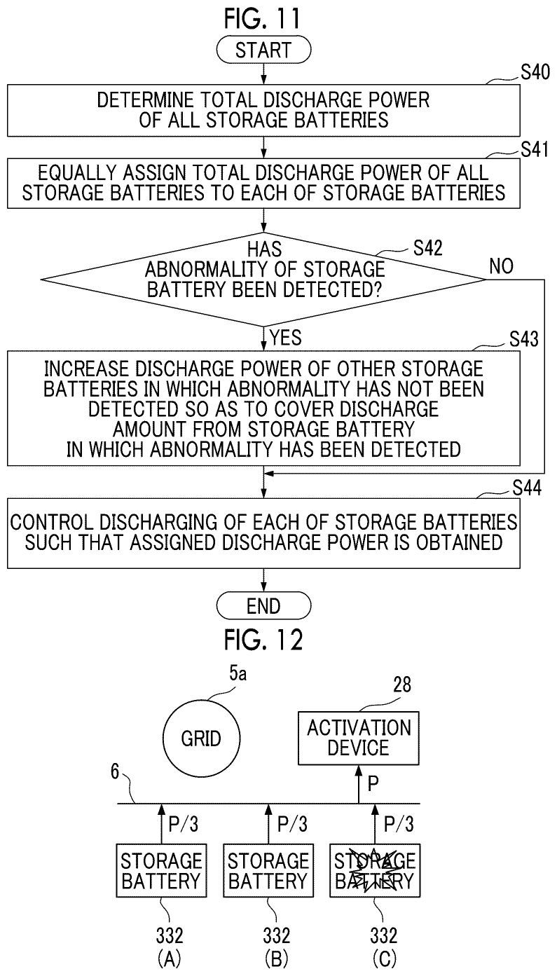

Hereinafter, a power generation system and a control method according to an embodiment of the present disclosure will be described with reference to FIGS. 1 to 17. FIG. 1 is a configuration diagram showing a configuration example of a power generation system according to an embodiment of the present disclosure. FIG. 2 is a schematic diagram showing an operation example of the power generation system according to the embodiment of the present disclosure. FIG. 3 is a schematic diagram showing an example of an activation process of a gas turbine according to the embodiment of the present disclosure. FIG. 4 is a schematic diagram for describing an operation example of the power generation system according to the embodiment of the present disclosure. FIGS. 5 and 6 are flowcharts showing operation examples of the power generation system according to the embodiment of the present disclosure. FIGS. 7 to 9 are schematic diagrams for describing operation examples of the power generation system according to the embodiment of the present disclosure. FIGS. 10 and 11 are flowcharts showing operation examples of the power generation system according to the embodiment of the present disclosure. FIGS. 12 to 17 are schematic diagrams for describing operation examples of the power generation system according to the embodiment of the present disclosure. In each drawing, the same reference numerals will be assigned to the same or corresponding configurations, and description thereof will be omitted as appropriate.

### (Configuration of Power Generation System)

As shown in FIG. 1, a power generation system 1 according to the present embodiment includes a power generation facility 2 and a power storage facility 3. An input/output line 11 of the power of the power generation facility 2 is connected to a power transmission and distribution line 6 via a power meter 73. An input/output line 12 of the power of the power storage facility 3 is connected to the power transmission and distribution line 6. An input/output line 13 of the power of a production facility 4 is connected to the power transmission and distribution line 6. The power transmission and distribution line 6 is connected to a system 5 via a transformer 72 and a power meter 71. The system 5 is also referred to as a power system. In the present embodiment, the power input from the system 5 to the power transmission and distribution line 6 is referred to as received power. The power output from the power generation facility 2 to the power transmission and distribution line 6 is referred to as generated power. The power input from the power transmission and distribution line 6 to the power generation facility 2 is referred to as power consumption of the power generation facility. The power output from the power storage facility 3 to the power transmission and distribution line 6 is referred to as discharge power. The power input from the power transmission and distribution line 6 to the power storage facility 3 is referred to as charge power. The power input from the power transmission and distribution line 6 to the production facility 4 is referred to as power consumption of the production facility. The production facility 4 is, for example, a facility in a factory, and consumes power supplied from the power transmission and distribution line 6 as a load. In addition, the system 5 is a system that performs power generation, power transformation, power transmission, and power distribution. A portion of the system 5 that performs power transmission and power distribution is a grid 5a. In addition, the power transmission and distribution line 6 is also a grid. The charging of the power storage facility 3 is performed from the grid.

FIG. 2 shows an example of a daily change in the received power received by the power generation system 1 and the production facility 4 shown in FIG. 1. The horizontal axis represents time, and the vertical axis represents the received power. In the example shown in FIG. 2, the power generation facility 2 stops power generation at night and generates power only during the day. Until the power generation facility 2 starts power generation, the power is received from the system 5 including the activation power of the power generation facility 2. When the power generation facility 2 completes the activation and starts the power generation, the power is supplied from the power generation facility 2 to the production facility 4, and the received power becomes zero.

### (Configuration of Power Generation Facility)

The power generation facility 2 includes a gas turbine combined cycle (GTCC) power generation system 20 (hereinafter, referred to as a GTCC power generation system 20). The power generated by the power generation facility 2 is consumed as, for example, power consumption of the production facility or charge power, or is backflowed to the system 5. The GTCC power generation system 20 includes a gas turbine 21, a power generator 22, a steam turbine 23, a heat recovery steam generator 24, a condenser 25, a thyristor rectifier for excitation 26, a GTCC control device 27, and an auxiliary machine (not shown). The power generator 22 and the thyristor rectifier for excitation 26 are included in an activation device 28. The activation device 28 uses the power generator 22 as a motor to drive the gas turbine 21 when activating the gas turbine 21. The auxiliary machine (not shown) includes, for example, a pump that sends out circulating water, feed water, lubricant, or the like, a fan for cooling, and a facility in a monitoring room.

The gas turbine 21 is one aspect of a rotary machine, and includes an air compressor 211, a combustor 212, and a turbine 213. The gas turbine 21 is a prime mover that allows the combustor 212 to mix and combust air compressed by the air compressor 211 and a natural gas as a fuel, applies a combustion gas, which is a fluid, to rotary vanes in the turbine 213, and converts kinetic energy of the fluid into rotary motion to obtain rotational power. The gas turbine 21 drives the power generator 22.

In the present embodiment, an example in which the rotary machine is the gas turbine 21 will be described. However, the other embodiments are not limited thereto. In the other embodiments, the rotary machine may be, for example, an activation device of a gas turbine, a compressor, a centrifugal chiller, a pump, or the like.

The heat recovery steam generator 24 recovers exhaust heat of a gas turbine exhaust gas 241 discharged from the gas turbine 21 to generate steam. Further, the heat recovery steam generator 24 recovers the exhaust heat from the gas turbine exhaust gas 241 and performs denitrification treatment or the like, thereafter discharges a gas as a heat recovery steam generator exhaust gas 242, and discharges the gas into the atmosphere from a chimney (not shown) or the like.

The power generator 22 is a synchronous electric machine and is coaxially configured with the gas turbine 21 and the steam turbine 23. The power generator 22 operates as a synchronous power generator that converts the power of the gas turbine 21 and the steam turbine 23 into electric power and outputs the power to the power transmission and distribution line 6. In addition, when the gas turbine 21 is activated, the power generator 22 inputs power supplied from the power transmission and distribution line 6 and operates as a synchronous electric motor.

The steam turbine 23 is a prime mover that obtains rotational power by applying the steam generated by the heat recovery steam generator 24 to the rotary vanes.

The condenser 25 condenses the steam that has passed through the steam turbine 23. The water condensed by the condenser 25 is supplied to the heat recovery steam generator 24 via a pump or the like.

The GTCC control device 27 inputs a detection signal of various sensors (not shown), a control signal from a higher-level control device (not shown), and the like, and controls various actuators in the power generation facility 2. The GTCC control device 27 controls each part of the gas turbine 21 and controls the rotation speed and the output torque of the activation device 28, for example, when the gas turbine 21 is activated. In addition, the GTCC control device 27 generates a plurality of types of sign signals corresponding to a predetermined event when activating the gas turbine, and outputs the sign signals to the power storage facility control device 34 to be described later in the power storage facility 3 via a communication line 81. Examples of the predetermined event include a start of activation of the gas turbine, reaching of a spin rotation speed, ignition, and a self-rotation speed. In addition, the sign signal is a signal corresponding to each event, such as a gas turbine activation start signal, a spin rotation speed reaching signal, an ignition signal, and a self-rotation speed signal, and a signal representing the rotation speed of the gas turbine 21, or the like.

The start of activation of the gas turbine is an event in which the activation device 28 is activated and the application of a rotation torque is started from the activation device 28 to the gas turbine 21 in a turning state. The reaching of the spin rotation speed is an event in which the spin rotation speed reaches a predetermined rotation speed suitable for the purge operation of the exhaust duct of the gas turbine 21 that is being spin operated. Here, the spin operation is also called cranking, and is an operation in a state where the gas turbine 21 is driven only by the activation device 28 without fuel being injected into the gas turbine 21. In addition, the purge operation is a spin operation for eliminating unburned fuel remaining in the combustor 212, the duct, or the like before ignition at the time of activation. The ignition is an event in which the combustion of the fuel is started by the ignition operation. The self-rotation speed is an event in which the rotation speed is equal to or higher than a rotation speed at which a self-operation, in which the gas turbine 21 can maintain acceleration without receiving a rotation torque from the activation device 28, can be performed. The self-rotation speed means that the activation is completed.

FIG. 3 schematically shows a change in the power consumption of the power generation facility and the rotation speed of the gas turbine when the gas turbine 21 is activated. The horizontal axis represents time, and the vertical axis represents the power consumption of the power generation facility and the rotation speed of the gas turbine. The power consumption of the power generation facility is indicated by a solid line. The rotation speed of the gas turbine is indicated by a chain line. The power consumption of the power generation facility includes gas turbine activation power (power covered by discharge power) and the power consumption of the auxiliary machine. In FIG. 3, the gas turbine activation power amount (region covered by the discharge power) is shown by a right-upward hatching. In addition, the power consumption amount of the auxiliary machine is indicated by a right-downward hatching. The gas turbine activation power is power consumed by the activation device 28. In the example shown in FIG. 3, the activation of the gas turbine is started at time t1. The rotation speed of the gas turbine 21 reaches a predetermined spin rotation speed at time t2. Thereafter, the rotation speed of the gas turbine 21 is substantially controlled to be constant, and the purge operation is performed. Then, the ignition is performed at time t3. After the ignition, the rotation speed of the gas turbine 21 is increased and reaches the self-rotation speed at time t4. In addition, the gas turbine activation power is increased at a substantially constant increasing rate from time t1 to time t2. In addition, the gas turbine activation power is substantially constant from time t2 to time t3. In addition, the gas turbine activation power is increased front time t3, becomes constant at a certain value, and is decreased from a certain time close to time t4. Then, the value becomes zero at time t4. The change at the time of activation shown in FIG. 3 is an example, and the application of the present embodiment is not limited to this example.

### (Configuration of Power Storage Facility)

The power storage facility 3 includes an AC/DC converter 31, three DC/C converters 32, three storage battery packs 33, and the power storage facility control device 34. The AC/DC converter 31 is a bidirectional AC-DC converter, and converts the alternating current (AC) power input from the power transmission and distribution line 6 into the direct current (DC) power to output the DC power to the DC/DC converters 32, or converts the DC power input from the DC/DC converters 32 into the AC power to output the AC power to the power transmission and distribution line 6. The number of the DC/DC converters 32 and the number of the storage battery packs 33 may be one or a plurality of three or more.

The DC/DC converter 32 is a bidirectional DC-DC converter, and boosts or reduces the voltage of the DXC power input from the AC/DC converter 31 to output the DC power to the storage battery packs 33, or boosts or reduces the voltage of the DC, power input from the storage battery packs 33 to output the DC power to the AC/DC converter 31. In addition, for example, when the storage battery packs 33 are discharged, the DC/DC converters 32 control the discharge power from the storage battery packs 33 by setting the voltage of the DX power output to, for example, the AC/DC converter 31 to a constant value and changing the current in accordance with an instruction from the power storage facility control device 34. Each of the DC/DC converters 32 independently controls the discharge power from each of the storage battery packs 33 in accordance with the instruction front the power storage facility control device 34.

The storage battery pack 33 includes a circuit breaker 331, a storage battery 332, a sensor unit 333, and a monitoring device 334. The storage battery 332 is configured by a combination of a plurality of storage battery cells (single batteries) or a storage battery module (battery pack) formed of a plurality of storage battery cells. The storage battery cell is, for example, a lithium ion battery (however, the storage battery cell is not limited thereto). The storage battery 332 is discharged, for example, when the gas turbine 21 is activated. The circuit breaker 331 connects or disconnects the connection between the storage battery 332 and the DC/DC converter 32. The operation of the circuit breaker 331 is controlled by, for example, the monitoring device 334. The sensor unit 333 includes a plurality of types of sensors, detects the voltage, the current, the temperature, or the like of the storage battery 332, and outputs the detection result to the monitoring device 334. The monitoring device 334 acquires the detection result of the sensor unit 333, controls the circuit breaker 331, or calculates the State Of Charge (SOC; charging rate or charging state) of the storage battery 332. In addition, the monitoring device 334 outputs the acquired detection result of the sensor unit 333 or the information representing the calculated SOC to the power storage facility control device 34. In addition, the monitoring device 334 opens the circuit breaker 331 to protect the storage battery 332 in a case where a predetermined event such as overvoltage, overcurrent, or overheating is detected based on the detection result of the sensor unit 333. At that time, the monitoring device 334 outputs a signal indicating that the circuit breaker 331 has been opened to the power storage facility control device 34. In addition, the monitoring device 334 opens or closes the circuit breaker 331 when a predetermined instruction is received from the power storage facility control device 34.

The power storage facility control device 34 can be configured by using, for example, a computer, peripheral circuits, and peripheral devices. The power storage facility control device 34 includes a discharge control unit 341, a storage battery remaining power amount calculation unit 342, a power difference calculation unit 343, and an abnormality detection unit 344, as a functional configuration configured by a combination of hardware such as a computer and software such as a program.

The discharge control unit 341 controls discharging of one or more of the storage batteries 332. In the present embodiment, “controlling the discharging of the storage battery 332” means at least one of controlling the discharge power of the storage battery 332 and controlling the discharge power and the discharge power amount of the storage battery 332. When the gas turbine 21 is activated, for example, in a case where the remaining power amount of the storage battery 332 is sufficient, the discharge control unit 341 controls the discharge power in a predetermined pattern to discharge the storage battery 332. In addition, when the gas turbine 21 is activated, the discharge control unit 341 changes the pattern to discharge the storage battery 332 such that the discharge power amount does not exceed the remaining power amount in a case where, for example, the remaining power amount of the storage battery 332 is not sufficient.

In the present embodiment, the discharge control unit 341 controls the discharging from the storage battery 332, for example, corresponding to a predetermined event at the time of the activation of the gas turbine 21. The event includes at least one of the start of activation of the gas turbine 21, the reaching of the spin rotation speed, the ignition, or the self-rotation speed, as described above with reference to FIG. 3. The discharge amount control unit 341 receives a signal representing an event as the sign signal from the GTCC control device 27. The GTCC control device 27 is a configuration example of the control unit of the gas turbine 21.

In the present embodiment, when the gas turbine 21 is activated, the discharge control unit 341 controls the discharging from the storage battery 332 such that the power required for the activation of the gas turbine 21 can be covered by the power front the system 5 and the discharge power from the storage battery 332.

In addition, in a case where the power used for activation of the gas turbine 21 is supplied from the plurality of storage batteries 332 by the discharging from the plurality of storage batteries 332, when the abnormality detection unit 344 detects the abnormality of the storage battery 332, the discharge control unit 341 supplies, from the grid 5a, the discharge amount from the storage battery 332 in which the abnormality has been detected, and then increases the discharge power of the other storage batteries 332 in which the abnormality has not been detected to cover the discharge amount from the storage battery 332 in which the abnormality has been detected.

The storage battery remaining power amount calculation unit 342 calculates the remaining power amount of the storage battery 332. The storage battery remaining power amount calculation unit 342 acquires, for example, the SOC calculated by the monitoring device 334 and calculates the total remaining power amount of the three storage batteries 332. Alternatively, the storage battery remaining power amount calculation unit 342 calculates and integrates the charge power and the discharge power based on, for example, the current and the voltage detected by the monitoring device 334 to calculate the remaining power amount.

The power difference calculation unit 343 calculates the power difference between the predicted value of the received power from the system 5 at the time of the activation of the gas turbine 21 and the total power value that is available from the system 5. The power difference calculation unit 343 receives, for example, information representing a predicted value of the received power from a device that manages the production facility 4 via the communication line 81. FIG. 4 shows an example of the calculation of the power difference ΔMW. The horizontal axis represents time, and the vertical axis represents the received power. In FIG. 4, the actual values of the received power are shown in rectangular shapes by solid lines, and the predicted values are shown in rectangular shapes by broken lines. In addition, the gas turbine activation power in the predicted value is shown by hatching. In the example shown in FIG. 4, the gas turbine 21 starts activating after 8:30, and the received power reaches a peak at around 9:00 when the gas turbine activation power is maximized. The received power is decreased from around 9:30 when the power generator 22 starts to output the power, and the received power becomes zero around 10:00 or later. In the example shown in FIG. 4, when the value of the maximum contracted power is set as the available total power value, the power difference ΔMW is the value obtained by subtracting the predicted value of the received power MW from the system 5 at the time of the activation of the gas turbine 21 from the value of the maximum contracted power. The available total power value is not limited to the value of the maximum contracted power and can be set as, for example, an upper limit value set to achieve a predetermined purpose.

The abnormality detection unit 344 detects the abnormality in the storage battery 332 based on the information acquired from each monitoring device 334. The abnormality of the storage battery 332 is, for example, that the monitoring device 334 has opened the circuit breaker 331, or that the temperature of the storage battery 332 has exceeded a predetermined temperature.

### (Operation Example of Power Generation System 1)

An operation example when the gas turbine 21 of the power generation system 1 shown in FIG. 1 is activated will be described with reference to FIGS. 5 to 17. FIG. 5 shows a basic operation flow when the gas turbine 21 is activated. As shown in FIG. 5, in the power generation system 1, the power storage facility control device 34 determines the discharge mode of the storage battery 332 when the gas turbine 21 is activated (step S1), and controls the discharging of the storage battery 332 in the determined discharge mode (step S2). In the present embodiment, the discharge mode represents a mode of discharging from the power storage facility 3. In the present embodiment, as an example, a discharge mode in which discharging is not performed (discharging stop), a discharge mode in which a relatively large amount of the power of the storage battery 332 is used (large-discharge mode), a discharge mode in which the power of the storage battery 332 is moderately used (medium-discharge mode), and a discharge mode in which the power of the storage battery 332 is used only in the peak portion (small-discharge mode) are set, and any of these discharge modes is used to perform or not to perform discharging. The processes shown in FIG. 5 may be started, for example, according to a predetermined input operation of the operator, or may be started in a case where a predetermined signal is received from the power generation facility 2 or the production facility 4 or in a case where a predetermined time is reached.

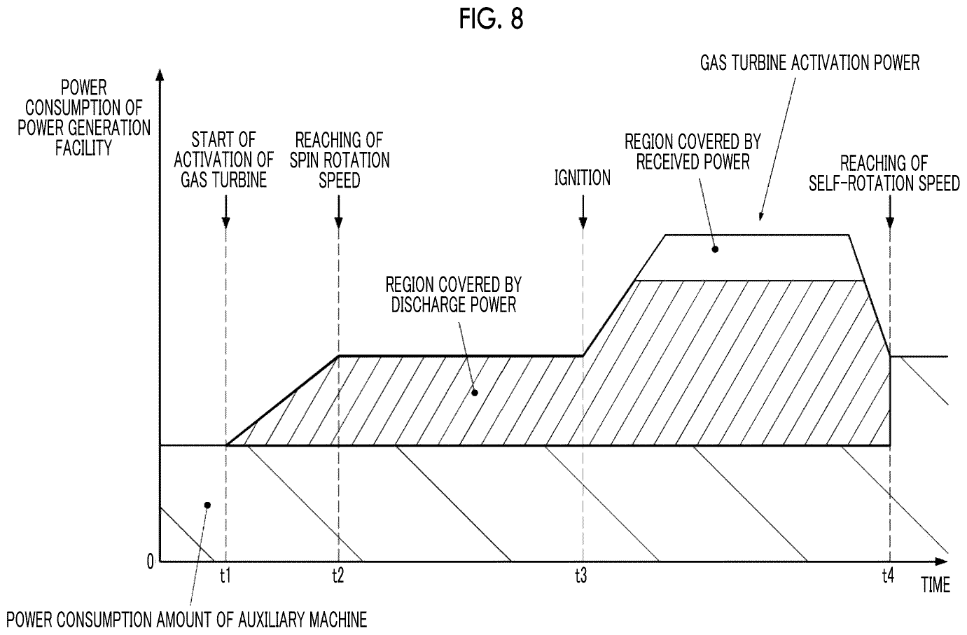

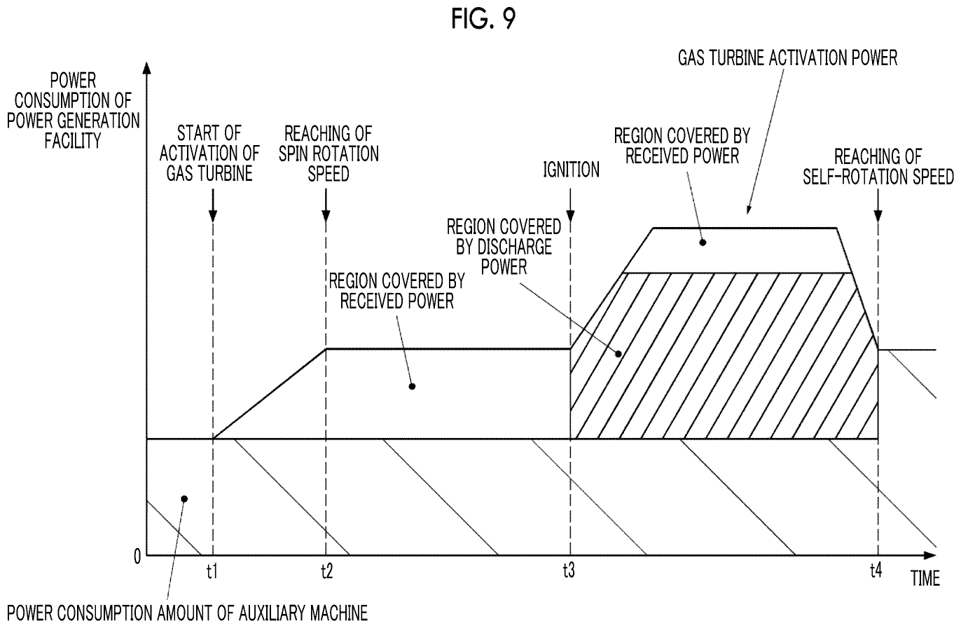

Next, a process (step S1) of determining a discharge mode shown in FIG. 5 will be described. FIG. 6 shows a flow of step S1 of determining the discharge mode shown in FIG. 5. FIG. 7 shows an example of a large-discharge mode. FIG. 8 shows an example of a medium-discharge mode. FIG. 9 shows an example of a small-discharge mode. FIGS. 7 to 9 show examples of the same power consumption of the power generation facility as shown in FIG. 3. However, in FIGS. 7 to 9, the gas turbine activation power amount shown by the right-upward hatching in FIG. 3 is shown by dividing the right-upward hatched portion (region covered by the discharge power) and the white portion (region covered by the received power). In the large-discharge mode shown in FIG. 7, the region covered by the gas turbine activation power matches the region covered by the discharge power in all periods from the start of the activation to the self-rotation speed. In the medium-discharge mode shown in FIG. 8, a region covered by the received power is set for a part of the period from the ignition to the self-rotation speed. In the small-discharge mode shown in FIG. 9, a region covered by the received power is set for all periods from the start of the activation of the gas turbine to the ignition and a part of the period from the ignition to the self-rotation speed. In the present operation example, it is assumed that the power storage facility 3 stores a power amount that can sufficiently cover at least the discharge power amount in the small-discharge mode (for example, to the extent that the activation can be performed a plurality of times) before the gas turbine 21 is activated.

In the process shown in FIG. 6, the power difference calculation unit 343 acquires the predicted value of the received power MW[W] (step S10) and calculates the power difference ΔMW (step S11). Next, the storage battery remaining power amount calculation unit 342 calculates the remaining power amount BR [Wh] of the storage battery 332 (step S12).

Next, the discharge control unit 341 determines whether the power difference ΔMW[W] is larger than “0” (step S13). In a case where the power difference ΔMW[W] is larger than “0” (step S13: YES), the discharge control unit. 341 determines the discharge mode to be the “discharging stop” (step S4), and ends the process shown in FIG. 6. In a case where the power difference ΔMW[W] is not larger than “0” (step S13: NO), the discharge control unit 341 determines whether the remaining power amount BR is larger than the discharge power amount [Wh] in the large-discharge mode (step S15). Here, the discharge power amount [Wh] in the large-discharge mode corresponds to the area of the right-upward hatched portion shown in FIG. 7.

In a case where the remaining power amount BR is larger than the discharge power amount [Wh] in the large-discharge mode (step S15: YES), the discharge control unit 341 determines the discharge mode to be the “large-discharge mode” (step S16), and ends the process shown in FIG. 6. In a case where the remaining power amount BR is not larger than the discharge power amount [Wh] in the large-discharge mode (Step S15: NO), the discharge control unit 341 determines whether the remaining power amount BR is larger than the discharge power amount [Wh] in the medium-discharge mode (Step S7). Here, the discharge power amount [Wh] in the medium-discharge mode corresponds to the area of the right-upward hatched portion shown in FIG. 8.

In a vase where the remaining power amount BR is larger than the discharge power amount [Wh] in the medium-discharge mode (step S17: YES), the discharge control unit 341 determines the discharge mode to be the “medium-discharge mode” (step S18), and ends the process shown in FIG. 6. In a case where the remaining power amount BR is not larger than the discharge power amount [Wh] in the medium-discharge mode (step S17: NO), the discharge control unit 341 determines the discharge mode to be the “small-discharge mode” (step S19), and ends the process shown in FIG. 6.

The determination processes in Step S13. Step S15, and Step S17 may be performed with a certain margin to determine the magnitude relation. For example, in Step S13, it may be determined whether the value is larger than a certain margin “α” (α>0) instead of whether the value is larger than “0”.

Next, a process of controlling discharging (step S2) shown in FIG. 5 will be described. FIG. 10 shows a flow of Step S2 of controlling the discharging shown in FIG. 5. FIG. 11 shows a processing flow performed in the processes of controlling the discharging from the storage battery 332 in FIG. 10 (steps S23, S24, S26, and S28).

In the processes shown in FIG. 10, the discharge power from the power storage facility 3 is controlled according to the pattern shown in FIGS. 7 to 9, with the reception of the predetermined sign signal as a trigger. For example, in the large-discharge mode shown in FIG. 7, the discharging from the power storage facility 3 is stated after the gas turbine activation start signal has been received at time t1. Thereafter, the discharge power is increased at a predetermined increasing rate corresponding to the elapsed time from time t1. Thereafter, when the spin rotation speed reaching signal is received at time t2, the discharge power is controlled to a predetermined constant value. Thereafter, when the ignition signal is received at time t3, the discharge power is gradually increased at a predetermined increasing rate corresponding to the elapsed time front time t3. Then, the discharge power is controlled to a predetermined constant value when the discharge power reaches a predetermined value. Thereafter, for example, when the elapsed time from time t3 reaches a predetermined value, the discharge power is decreased at a predetermined decreasing rate. Thereafter, when the self-rotation speed signal is received at time t4, the discharging from the power storage facility 3 is stopped. The control of the discharge power is not limited thereto, and for example, the discharge power may be increased or decreased corresponding to the rotation speed of the gas turbine 21.

In the processes shown in FIG. 10, first, the discharge control unit 341 determines whether the discharge mode is in the discharging stop (step S20). When the discharge mode is in the discharging stop (step S20: YES), the discharge control unit 341 ends the process shown in FIG. 10 without performing the discharging from the power storage facility 3. When the discharge mode is not in the discharging stop (step S20: NO), the discharge control unit 341 waits for the reception of the gas turbine activation start signal (repetition of step S21: NO). When the gas turbine activation start signal has been received (step S21: YES), the discharge control unit 341 determines whether the discharge mode is the large-discharge mode or the medium-discharge mode (step S22). In a case where the discharge mode is the large-discharge mode or the medium-discharge mode (step S22: YES), the discharge control unit 341 starts discharging front the storage battery 332 (step S23). Next, the discharge control unit 341 increases the discharge power at a predetermined increasing rate corresponding to the elapsed time from when the gas turbine activation start signal has been received (step S24). Next, the discharge control unit 341 determines whether the spin rotation speed reaching signal has been received (step S25). When the spin rotation speed reaching signal has not been received (step S25: NO), the discharge control unit 341 increases the discharge power again at a predetermined increasing rate corresponding to the elapsed time from when the gas turbine activation start signal has been received (step S24). The process in Step S24 and the process in Step S25 are performed at a constant cycle (that is, a constant standby time is set between the repeated processes).

In a case where the spin rotation speed reaching signal is received (step S25: YES), the discharge control unit 341 controls the discharge power to a predetermined constant value (step S26). Next, the discharge control unit 341 determines whether the ignition signal has been received (step S27). When the ignition signal has not been received (step S27: NO the discharge control unit 341 continues to control the discharge power at a predetermined constant value (step S26). The process in step S26 and the process in step S27 are performed at a constant cycle.

On the other hand, when the discharge mode is not the large-discharge mode or the medium-discharge mode (step S22: NO), the discharge control unit 341 waits for the reception of the ignition signal (repetition of step S31: NO).

In a case where the ignition signal has been received in step S27 or step S31 (step S27: YES or step S31: YES), the discharge control unit 341 controls the discharge power in a predetermined pattern according to the discharge mode (step S28). Next, the discharge control unit 341 determines whether the self-rotation speed signal has been received (step S29). When the self-rotation speed signal has not been received (step S29: NO), the discharge control unit 341 continues to control the discharge power in a predetermined pattern according to the discharge mode (step S28). The process in step S28 and the process in step S29 are performed at a constant cycle.

In a case where the self-rotation speed signal has been received (step S29: YES), the discharge control unit 341 stops discharging from the storage battery 332 (step S30), and ends the process shown in FIG. 10.

Next, processes shown in FIG. 11 will be described. As described above, the processes shown in FIG. 11 are the processes performed in steps S23, S24, S26, and S28 shown in FIG. 10. When the processes shown in FIG. 11 are started, the discharge control unit 341 first determines the total discharge power of all storage batteries (step S40).

In a case where the process shown in FIG. 11 is performed in step S23, the total discharge power of all storage batteries is determined only once by the suitable power at the time of the start of discharging. In a case where the process shown in FIG. 11 is performed in step S24, it is determined that the total discharge power of all storage batteries is increased at a predetermined increasing rate, for example, each time the process is performed. In a case where the process shown in FIG. 11 is performed in step S26, the total discharge power of all storage batteries is always determined to a constant predetermined value. In a case where the process shown in FIG. 11 is performed in step S28, the total discharge power of all storage batteries is determined according to the pattern shown in FIGS. 7 to 9 each time the process is performed.

Next, the discharge control unit. 341 equally assigns the total discharge power of all storage batteries to each of the storage batteries 332 (step S41). For example, in a case where the total discharge power of all storage batteries is P, the power of P/3 is equally assigned to the three storage batteries 332 in the present embodiment.

Next, the discharge control unit 341 determines whether the abnormality detection unit 344 has detected the abnormality of the storage battery 332 (step S42). On the other hand, in a case where the abnormality is not detected (step S42: NO), the discharge control unit 341 controls the discharging of each of the storage batteries 332 such that the assigned discharge power is obtained (step S44), and ends the process shown in FIG. 11.

On the other hand, in a case where the abnormality is detected (step S42: YES), the discharge control unit 341 increases the discharge power of the other storage batteries 332 in which the abnormality has not been detected so as to cover the discharge amount from the storage battery 332 in which the abnormality has been detected (step S43). For example, in a case where the abnormality of one storage battery 332 is detected, the discharge control unit 341 sets the discharge power assigned to the storage battery 332 to “0” and increases the discharge power amount assigned to the other storage batteries 332 to P/2. Next, the discharge control unit 341 controls the discharging of each of the storage batteries 332 such that the assigned discharge power is obtained (step S44), and ends the process shown in FIG. 11.

As described above, each process of step S24, step S26, and step S28 is performed at a constant cycle. Therefore, for example, in a case of the abnormality in which the circuit breaker 331 is opened by the monitoring device 334, a delay such as the cycle occurs until the discharge power of the other storage batteries 332 is increased after the circuit breaker 331 is opened. In this case, in a case where the power used for activation of the gas turbine 21 is supplied from the plurality of storage batteries 332 by the discharging from the plurality of storage batteries 332, when the abnormality detection unit 344 detects the abnormality of the storage battery 332, the discharge control unit. 341 supplies, from the grid 5a (or power transmission and distribution line 6), the discharge amount from the storage battery 332 in which the abnormality has been detected, and then increases the discharge power of the other storage batteries 332 in which the abnormality has not been detected to cover the discharge amount from the storage battery 332 in which the abnormality is detected.

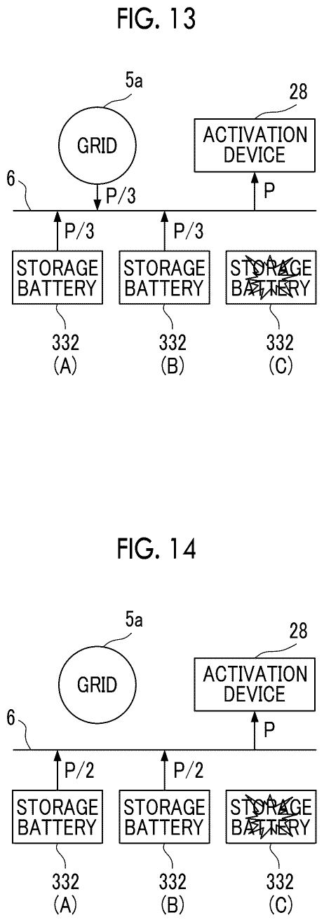

FIGS. 12 to 14 show an operation example in a case where the circuit breaker 331 is opened in one of the three storage batteries 332 when the gas turbine 21 is activated. In addition, in FIGS. 12 to 14, three storage batteries 332 are used as a storage battery 332 (A), a storage battery 332 (B), and a storage battery 332 (C). FIG. 12 shows a state where the storage battery 332 (C) has stopped discharging in a case where the activation power P is supplied equally from the storage battery 332 (A), the storage battery 332 (B), and the storage battery 332 (C) by P/3 each when the gas turbine 21 is activated. In this case, as shown in FIG. 13, the power of P/3 is supplied from the grid 5a before the discharge power of the other storage battery 332 (A) and the storage battery 332 (B) is increased. Thereafter, when the discharge power of the storage battery 332 (A) and the storage battery 332 (B) is increased, as shown in FIG. 14, the supply of the power from the grid 5a is stopped, and the power supply to the activation device 28 is continued only by the storage battery 332 (A) and the storage battery 332 (B).

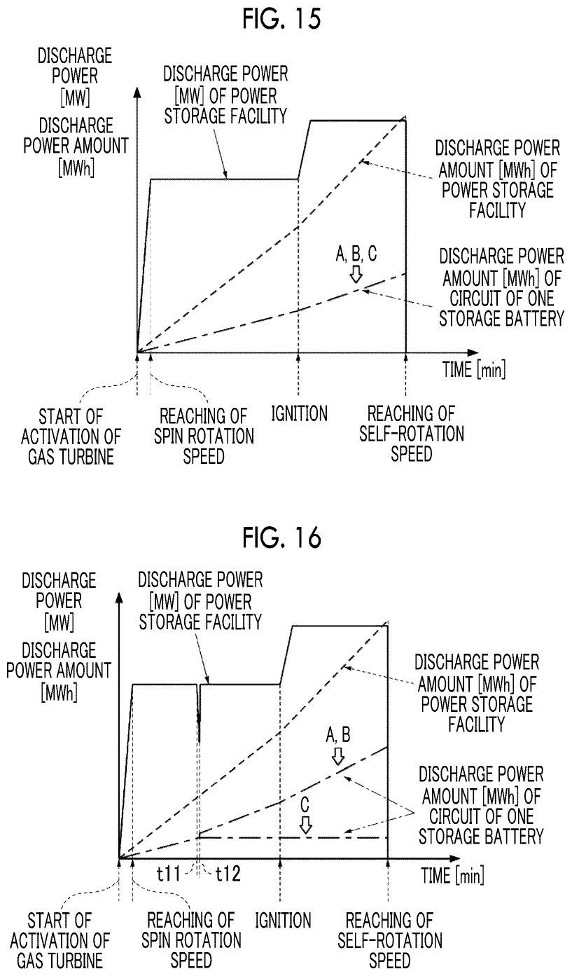

FIGS. 15 to 17 show examples of changes over time in the discharge power and the discharge power amount from the storage battery 332 (A), the storage battery 332 (B), and the storage battery 332 (C) when the gas turbine 21 is activated. A solid line represents the discharge power front the power storage facility 3. A broken line represents the discharge power amount from the power storage facility 3. A chain line represents the discharge power amount from each of the storage battery 332 (A), the storage battery 332 (B), and the storage battery 332 (C). FIG. 15 is a case where the storage battery 332 (A), the storage battery 332 (B), and the storage battery 332 (C) are all normal. FIG. 16 is a case where the storage battery 332 (C) has stopped discharging at time t11. In this case, the storage battery 332 (A) and the storage battery 332 (B) increase the discharge power at time t12. In this case, the decreasing amount in the discharge power from time t11 to time t12 is supplied from the grid 5a. FIG. 17 is a case where the storage battery 332 (C) has stopped discharging immediately before the start of activation. In this case, the storage battery 332 (A) and the storage battery 332 (B) increase the discharge power from the start of the activation.

### (Operations and Effects)

As described above, in the power generation system 1 of the present embodiment, in a case where the power used for activation of the gas turbine 21 is supplied from the plurality of storage batteries 332 by the discharging from the plurality of storage batteries 332, when the abnormality detection unit 344 detects the abnormality of the storage battery 332, the discharge control unit 341 supplies, from the grid 5a (or power transmission and distribution line 6 as a grid), the discharge amount from the storage battery 332 in which the abnormality has been detected, and then increases the discharge power of the other storage batteries 332 in which the abnormality has not been detected to cover the discharge amount from the storage battery 332 in which the abnormality has been detected. Therefore, it is possible to appropriately cope with the abnormality of the storage battery 332 for supplying the power to the activation device 28 of the gas turbine 21.

The storage battery 332 is discharged in any period from the start of the activation of the gas turbine 21 to the completion of the activation of the gas turbine 21. According to this configuration, the capacity of the storage battery 332 can be appropriately set.

In addition, the storage battery 332 is discharged in any period front the ignition of the gas turbine 21 to the completion of the activation of the gas turbine 21. According to this configuration, the capacity of the storage battery 332 can be appropriately set.

In addition, the charging of the storage battery 332 is performed from the grid 5a (or the power transmission and distribution line 6 as the grid).

In addition, the discharge control unit 341 equally controls the discharge power from each of the plurality of storage batteries 332. According to this configuration, the capacity of the storage battery 332 can be appropriately set.

### Other Embodiments

The embodiment of the present disclosure has been described in detail with reference to the drawings. However, the specific configurations are not limited to the embodiment, and the present disclosure includes design changes or the like without departing from the gist of the present disclosure.

In the above embodiments, the discharge control unit 341, the storage battery remaining power amount calculation unit 342, the power difference calculation unit 343, and the abnormality detection unit 344 are provided in the power storage facility 3. However, the present disclosure is not limited thereto, and the discharge control unit 341, the storage battery remaining power amount calculation unit 342, the power difference calculation unit 343, and the abnormality detection unit 344 may be provided in, for example, the GTCC control device 27.

### <Configuration of Computer>

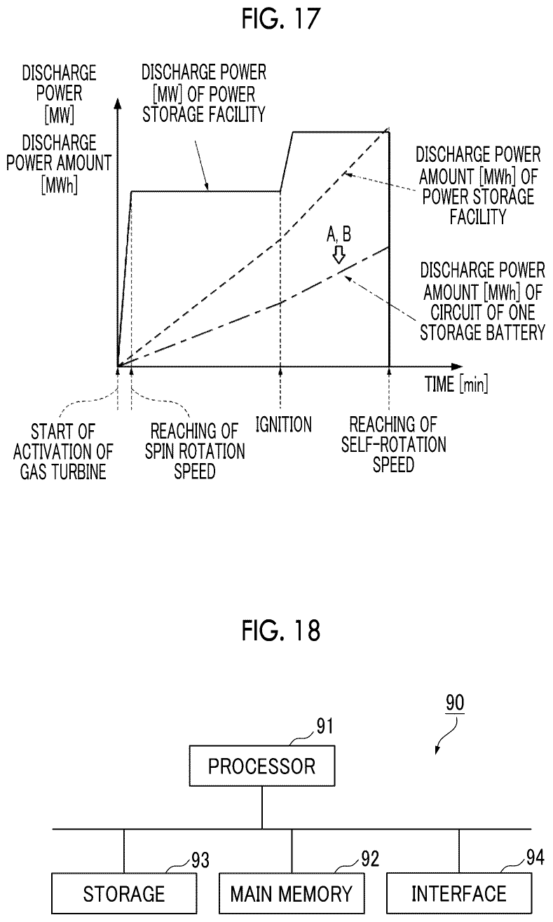

FIG. 18 is a schematic block diagram showing a configuration of a computer according to at least one embodiment.

A computer 90 includes a processor 91, a main memory 92, a storage 93, and an interface 94.

The above-described power storage facility control device 34 and the GTCC control device 27 are mounted on the computer 90. The operation of each processing unit described above is stored in the storage 93 in a form of a program. The processor 91 reads the program from the storage 93, loads the program into the main memory 92, and performs the above-described processes in accordance with the program. Further, the processor 91 ensures a storage area corresponding to each storage unit described above in the main memory 92 in accordance with the program.

The program may implement some of functions performed by the computer 90. For example, the program may implement the functions in combination with another program already stored in the storage or in combination with another program installed on another device. In another embodiment, in addition to the above-described configuration or instead of the above-described configuration, the computer may include a custom large scale integrated circuit (LSI) such as a programmable logic device (PLD). Examples of the PLD include a programmable array logic (PAL), a generic array logic (GAL), a complex programmable logic device (CP)), and a field programmable gate array (FPGA), in this case, some or all of the functions implemented by the processor may be implemented by the integrated circuit.

Examples of the storage 93 include a hard disk drive (HDD), a solid state drive (SSD), a magnetic disc, a magneto-optical disc, a compact disc read only memory (CD-ROM), a digital versatile disc read only memory (DVD-ROM), and a semiconductor memory. The storage 93 may be an internal medium directly connected to a bus of the computer 90, or may be an external medium connected to the computer 90 via the interface 94 or a communication line. In addition, when the program is distributed to the computer 90 via the communication line, the computer 90 receiving the distribution may load the program into the main memory 92, and may perform the above-described processes. In at least one embodiment, the storage 93 is a non-temporary tangible storage medium.

### <Additional Notes>

The power generation system 1 according to each of the above embodiments is understood as follows, for example.

(1) The power generation system 1 according to a first aspect includes the rotary machine (gas turbine 21), the plurality of storage batteries 332, the discharge control unit 341 that controls discharging of the plurality of storage batteries, and the abnormality detection unit 344 that detects the abnormality of the storage battery, in which in a case where the power used for activation of the rotary machine is supplied from the plurality of storage batteries by the discharging from the plurality of storage batteries, when the abnormality detection unit detects the abnormality of the storage batteries, the discharge control unit supplies, from the grid (grid 5a, power transmission and distribution line 6), the discharge amount from the storage battery in which the abnormality has been detected, and then increases the discharge power of the other storage batteries in which the abnormality has not been detected, to cover the discharge amount from the storage battery in which the abnormality has been detected. According to the present aspect and each of the following aspects, it is possible to appropriately cope with the abnormality of the storage battery 332 for supplying the power to the activation device 28 of the rotary machine.

(2) The power generation system 1 according to a second aspect is the power generation system 1 of (1), in which the storage batteries are discharged in any period from the start of activation of the rotary machine to the completion of the activation of the rotary machine. According to the present aspect, the capacity of the storage battery 332 for supplying the power to the activation device 28 of the gas turbine 21 can be appropriately set.

(3) The power generation system 1 according to a third aspect is the power generation system 1 of (1) or (2), in which the rotary machine is a gas turbine.

(4) The power generation system 1 according to a fourth aspect is the power generation system 1 of (3), in which the storage batteries are discharged in any period from the ignition of the gas turbine to the completion of activation of the gas turbine. According to the present aspect, the capacity of the storage battery 332 for supplying the power to the activation device 28 of the gas turbine 21 can be appropriately set.

(5) The power generation system 1 according to a fifth aspect is the power generation system 1 of (1) to (4), in which the charging of the storage batteries is performed from the grid.

(6) The power generation system 1 according to a sixth aspect is the power generation system 1 of (1) to (5), in which the discharge control unit equally controls the discharge power from each of the plurality of storage batteries. According to the present aspect, the capacity of the storage battery 332 for supplying the power to the activation device 28 of the rotary machine can be appropriately set.

### INDUSTRIAL APPLICABILITY

According to the power generation system and the control method of the present disclosure, it is possible to appropriately cope with the abnormality of the storage battery for supplying power to the activation device of the rotary machine.

### REFERENCE SIGNS LIST

1: power generation system
2: power generation facility
3: power storage facility
4: production facility
5: system
5a: grid
6: power transmission and distribution line (grid)
20: GTCC power generation system
21: gas turbine (rotary machine)
22: power generator
27: GTCC control device (control unit)
28: activation device
332: storage battery
341: discharge control unit
342: storage battery remaining power amount calculation unit
343: power difference calculation unit
344: abnormality detection unit

1. A power generation system comprising:
a rotary machine;
a plurality of storage batteries;
a discharge control unit that controls discharging of the plurality of storage batteries; and
an abnormality detection unit that detects an abnormality of the storage battery,
wherein in a case where power used for activation of the rotary machine is supplied from the plurality of storage batteries by the discharging from the plurality of storage batteries, when the abnormality detection unit detects the abnormality of the storage batteries, the discharge control unit supplies, from a grid, a discharge amount from the storage battery in which the abnormality has been detected, and then increases discharge power of the other storage batteries in which the abnormality has not been detected, to cover the discharge amount from the storage battery in which the abnormality has been detected.

2. The power generation system according to claim 1, wherein
the storage batteries are discharged in any period from a start of activation of the rotary machine to completion of the activation of the rotary machine.

3. The power generation system according to claim 1, wherein
the rotary machine is a gas turbine.

4. The power generation system according to claim 3, wherein
the storage batteries are discharged in any period from ignition of the gas turbine to completion of activation of the gas turbine.

5. The power generation system according to claim 4, wherein
charging of the storage batteries is performed from the grid.

6. The power generation system according to claim 5, wherein
the discharge control unit equally controls the discharge power from each of the plurality of storage batteries.

7. A control method of a power generation system including a rotary machine, a plurality of storage batteries, a discharge control unit that controls discharging of the plurality of storage batteries, and an abnormality detection unit that detects an abnormality of the storage battery,
the control method comprising:
causing, in a case where power used for activation of the rotary machine is supplied from the plurality of storage batteries by the discharging from the plurality of storage batteries, when the abnormality detection unit detects the abnormality of the storage batteries, the discharge control unit supplies, from a grid, a discharge amount from the storage battery in which the abnormality has been detected, and then increases discharge power of the other storage batteries in which the abnormality has not been detected, to cover the discharge amount from the storage battery in which the abnormality has been detected.

8. The power generation system according to claim 2, wherein
the rotary machine is a gas turbine.
